(19) United States
(12) Patent Application Publication
(10) Pub. No.: US 2024/0071806 A1
(43) Pub. Date: Feb. 29, 2024

(54) APPARATUS FOR HEATING WAFER

(71) Applicant: Samsung Electronics Co., Ltd., Suwon-si (KR)

(72) Inventors: Jeongdu Kim, Suwon-si (KR); Sunghyup Kim, Suwon-si (KR); Junhyoun Park, Suwon-si (KR); Junghwan Hwang, Suwon-si (KR); Dahee Jin, Suwon-si (KR); Geonsoo Choi, Suwon-si (KR)

(21) Appl. No.: 18/321,164

(22) Filed: May 22, 2023

(30) Foreign Application Priority Data
Aug. 25, 2022 (KR) 10-2022-0106934

(51) Int. Cl. H01L 21/687; H01L 21/67

(52) U.S. Cl. CPC H01L 21/6875; H01L 21/67103; H01L 21/68757

(57) ABSTRACT

An apparatus for heating a wafer includes a heater, a heating block on an upper surface of the heater, and a plurality of support protrusions protruding from an upper surface of the heating block, wherein the upper surface of the heating block has a curved shape with a concave central portion, and at least the support protrusion at the central portion of the heating block, among the plurality of support protrusions, is configured to be deformed in response to heating by the heater.

### CROSS-REFERENCE TO RELATED APPLICATION(S)

This application claims benefit of priority to Korean Patent Application No. 10-2022-0106934, filed on Aug. 25, 2022 in the Korean Intellectual Property Office, the disclosure of which is incorporated herein by reference in its entirety.

### BACKGROUND

The present inventive concept relates to an apparatus for heating a wafer.

Recently, as semiconductor products have been miniaturized and bonding processes of two or more stacks are applied, warpage of a wafer has increased. Meanwhile, the increase in warpage of the wafer may deteriorate a temperature distribution of major semiconductor processes, causing various quality problems. Typically, there is a high risk of defects occurring in an ashing process due to an increase in warpage of a wafer.

In addition, wafers having a stack structure manufactured using a bonding process may be detached at an edge region, and in this case, when applying electrostatic force using an electrostatic chuck during a subsequent process, the risk of the occurrence of arcing is high.

In order to prevent this, a wafer is heated, but there is a problem in that a heat transfer rate distribution between wafer and a heater increases as the warpage of wafer increases.

### SUMMARY

An aspect of the present inventive concept is to provide an apparatus for heating a wafer, capable of reducing a temperature difference in a central portion and an edge of wafer when the wafer with warpage is heated.

According to an aspect of the present inventive concept, an apparatus for heating a wafer includes a heater; a heating block on an upper surface of the heater; and a plurality of support protrusions protruding from an upper surface of the heating block, wherein the upper surface of the heating block has a curved shape with a concave central portion, and at least the support protrusion at the central portion of the heating block, among the plurality of support protrusions, is deformed in response to heating by the heater.

According to an aspect of the present inventive concept, an apparatus for heating a wafer includes a heater, a heating block on an upper surface of the heater and having a thickness difference between a central portion and an edge, and a plurality of support protrusions extending from an upper surface of the heating block, a portion thereof configured to be deformed in response to heat or power supplied thereto.

According to an aspect of the present inventive concept, an apparatus for heating a wafer includes a heater, a heating block on an upper surface of the heater and having a thickness difference between a central portion and an edge, and a plurality of support protrusions extending from an upper surface of the heating block, at least some of the plurality of support protrusions configured to be deformed in response to heating by the heater, wherein the plurality of support protrusions comprise a first support protrusion at the central portion of the heating block that is formed of a material that reduces in height in response to heat, and wherein the plurality of support protrusions comprise a second support protrusion adjacent the first support protrusion that is formed of a material that increases in height in response to heat.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a configuration diagram illustrating an apparatus for heating a wafer according to an example embodiment;

FIG. 2 is a schematic perspective view illustrating an apparatus for heating a wafer according to an example embodiment;

FIG. 3 is an enlarged view illustrating portion B of FIG. 2;

FIG. 4 is an enlarged view illustrating portion A of FIG. 2;

FIGS. 5 to 8 are diagrams illustrating an operation of an apparatus for heating a wafer according to an example embodiment;

FIG. 9 is a diagram illustrating a temperature of wafer during a wafer heating process by an apparatus for heating a wafer according to an example embodiment; and

FIG. 10 is a diagram illustrating an apparatus for heating a wafer according to an example embodiment.

### DETAILED DESCRIPTION

Hereinafter, example embodiments of the present inventive concept will be described with reference to the accompanying drawings.

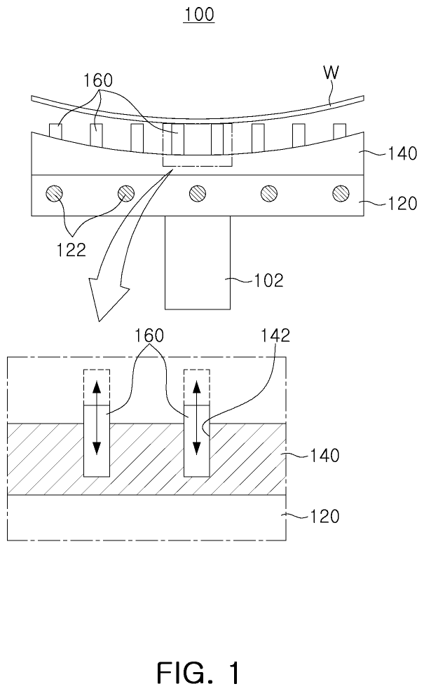

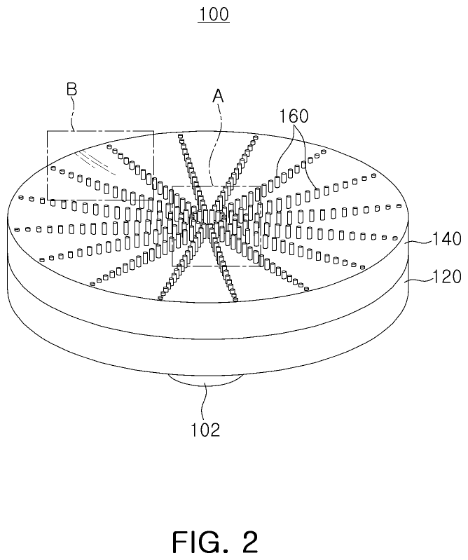

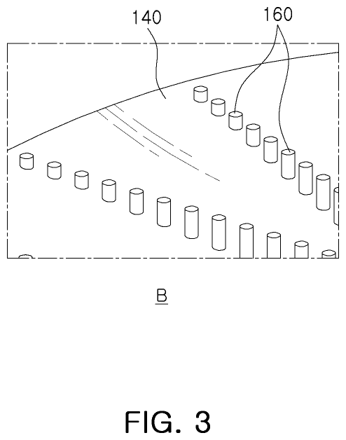

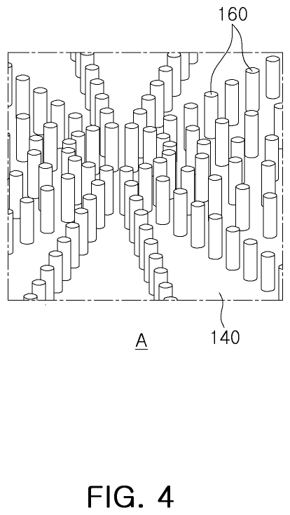

FIG. 1 is a configuration diagram illustrating an apparatus for heating a wafer according to an example embodiment.

Referring to FIG. 1, an apparatus 100 for heating a wafer according to an example embodiment includes a heater 120, a heating block 140, and a plurality of support protrusions or support members 160.

The heater 120 is disposed, for example, on an upper surface of a shaft 102 and may have a circular plate shape. Meanwhile, a hot wire or heating wire 122 for heating a wafer W may be embedded and disposed in the heater 120. In addition, when an external power source is connected to the hot wire 122 and the wafer W is seated on the support protrusion 160, heat is discharged from the hot wire 122 to heat the wafer W.

The heating block 140 is disposed on an upper surface of the heater 120. Meanwhile, a thickness of the heating block 140 may be different at a central portion and an edge. As an example, the upper surface of the heating block 140 may have a curved shape with a concave central portion (or concave upper surface). Also, as an example, the upper surface of the heating block 140 may have a shape corresponding to a shape of the wafer W on which warpage has occurred. However, the present inventive concept is not limited thereto, and the upper surface of the heating block 140 may be formed to have a step or stepped shape. Meanwhile, the heating block 140 may be detachably installed on the upper surface of the heater 120. Accordingly, various types of heating blocks 140 may be installed in or on the heater 120. Therefore, a heating block 140 suitable for the type of the wafer W may be selected and installed in or on the heater 120. Meanwhile, the heating block 140 may be provided with an insertion recess 142 into which at least a portion of the plurality of support protrusions 160 are received. Details thereof will be described below.

A plurality of support protrusions 160 are disposed to protrude or extend from the upper surface of the heating block 140. For example, among the plurality of support protrusions 160, at least the support protrusion 160 disposed in the central portion of the heating block 140 may be configured to be deformed and stretched. Meanwhile, among the plurality of support protrusions 160, the support protrusion 160 that is stretched (or a stretchable support protrusion) may be deformed when heat or power is supplied. For example, among the plurality of support protrusions 160, the stretchable support protrusion 160 disposed in the central portion of the heating block 140 and the other protrusions 160 that are not stretchable may be formed of different materials. For example, in the case in which the stretchable support protrusion 160 is deformed when heat is supplied thereto, the stretchable support protrusion 160, among the plurality of support protrusions 160, may be formed of a material having a coefficient of thermal expansion significantly different from that of the rest of the support protrusions 160 that are not stretched (or unstretchable support protrusions). As an example, when the unstretchable support protrusion 160, among the plurality of support protrusions 160, is formed of a material including silicon, the stretchable support protrusion 160 may be formed of a synthetic resin material having a significant difference in thermal expansion coefficient. As an example, the stretchable or deformable support protrusion 160 may include a support protrusion 160 formed of a material that expands (e.g., increases in height or length) when heat is applied and a support protrusion 160 formed of a material that compresses or contracts (e.g., decreases in height or length) when heat is applied. As used herein, the terms “stretchable” and “stretched” may mean “deformable” or “deformed” and may mean that the support protrusion may be expandable or contractable in response to heat or power.

Meanwhile, as an example, in a case in which the stretchable support protrusion 160 is deformed when power is supplied thereto, the stretchable support protrusion 160, among the plurality of support protrusions 160, may be formed of a piezoelectric material or a shape-memory alloy.

In addition, the plurality of support protrusions 160 may have a cylindrical shape. As such, since the plurality of support protrusions 160 have a cylindrical shape, permanent deformation of the shape such as twisting during expansion and contraction may be reduced. However, the present inventive concept is not limited thereto, and the shape of the plurality of support protrusions 160 may be variously changed, such as a polygonal columnar shape or an elliptical columnar shape.

Also, a lower end of at least the stretchable support protrusion 160, among the plurality of support protrusions 160, may be inserted into the insertion recess 142 provided in the heating block 140. In addition, the stretchable support protrusion 160 may be guided to expand and contract in a (vertical) length direction by the insertion recess 142.

Meanwhile, upper surfaces of the plurality of support protrusions 160 before deformation of the stretchable support protrusion 160, among the plurality of support protrusions 160, may be coplanar or disposed on the same plane or at the same vertical level. To this end, a difference between a protruding height of the stretchable support protrusion 160 before deformation, among the plurality of support protrusions 160, from the heating block 140 and a protruding height of the support protrusion 160 disposed in the outermost portion may be 75 μm to 85 μm. For example, the protruding height of the stretchable support protrusion 160 from the heating block 140 before deformation of the stretchable support protrusion 160 may be approximately 100 μm, and the protruding height of the support protrusion 160 disposed in the outermost portion from the heating block 140 may be approximately 20 μm. Also, among the plurality of support protrusions 160, the height of the stretchable support protrusion 160 may be changed according to a heating time of the wafer W. For example, when the wafer W with warpage is seated on the plurality of support protrusions 160, the stretchable support protrusions 160 may be disposed to be in contact with a lower surface of the wafer W, and thereafter, when the wafer W is heated for a predetermined period of time, the protrusion 160 supporting a central portion of the wafer W is stretched or contracts and a portion thereof is disposed to be spaced apart from the central portion of the wafer W and the support protrusions 160 therearound may be disposed to support the lower surface of the wafer W.

Meanwhile, the heating block 140 may have a circular shape when viewed from above, and as an example, the plurality of support protrusions 160 may be disposed along a line passing through the center of the heating block 140 viewed from above. The plurality of support protrusions 160 may be arranged in lines extending radially outwardly from the center of the heating block 140. Accordingly, the density of the plurality of support protrusions 160 in a region disposed in the central portion of the heating block 140 may be higher than the density in a region disposed at the edge of the heating block 140. However, the arrangement position of the plurality of support protrusions 160 may be variously changed, and the plurality of support protrusions 160 may be arranged so that the central portion and the edge of the heating block 140 are similar in density.

Meanwhile, a lower end of at least the stretchable support protrusion 160, among the plurality of support protrusions 160, may be inserted into or received in the insertion recess 142 of the heating block 140. For example, among the plurality of support protrusions 160, the stretchable support protrusion 160 may be installed in the insertion recess 142 of the heating block 140, and the remaining support protrusions 160 may be integrally formed with or connected to the heating block 140. However, the present inventive concept is not limited thereto, and other support protrusions 160, excluding the stretchable support protrusion 160 may also be inserted into or received in the insertion recess 142 of the heating block 140.

Hereinafter, the operation of the apparatus for heating a wafer will be briefly described with reference to the drawings.

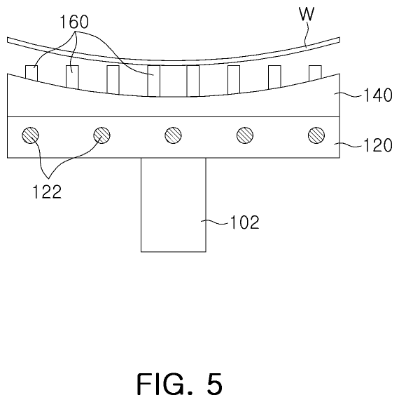

FIGS. 5 to 8 are diagrams illustrating the operation of the apparatus for heating a wafer according to an example embodiment.

First, referring to FIG. 5, the wafer W with warpage is seated on a plurality of support protrusions 160 of the apparatus 100 for heating a wafer. At this time, upper surfaces of the plurality of support protrusions 160 are disposed on the same plane. Also at this time, the central portion of the wafer W is in contact with the support protrusion 160 disposed in the central portion of the heating block 140 among the plurality of support protrusions 160, and the edge of the wafer W is spaced apart from the support protrusion 160 disposed at the edge of the heating block 140, among the plurality of support protrusions 160.

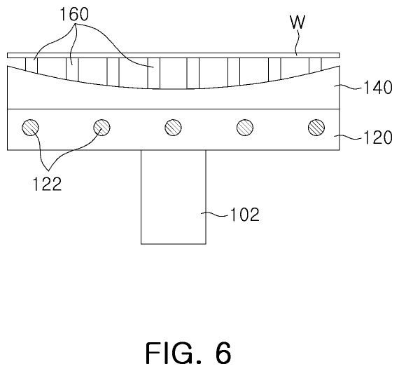

Thereafter, when the wafer W is heated by the heater 120, as illustrated in FIG. 6, the wafer W is deformed so that the entire lower surface of the wafer W is seated on the upper surface of the plurality of support protrusions 160.

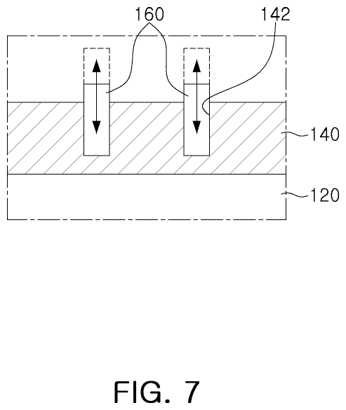

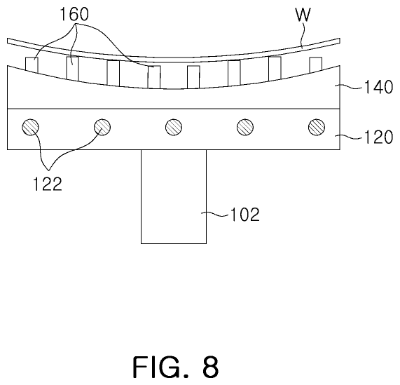

Thereafter, as heating by the heater 120 continues, as illustrated in FIG. 7, the support protrusion 160 disposed in the central portion of the heating block 140, among the plurality of support protrusions 160, is compressed or contracts and the support protrusion 160 disposed therearound expands. Accordingly, as illustrated in FIG. 8, while the support protrusion 160 disposed in the central portion of the heating block 140 is spaced apart from the wafer W, the support protrusion 160 disposed therearound comes into contact with the wafer W. Accordingly, heat may be more uniformly transferred to the wafer W.

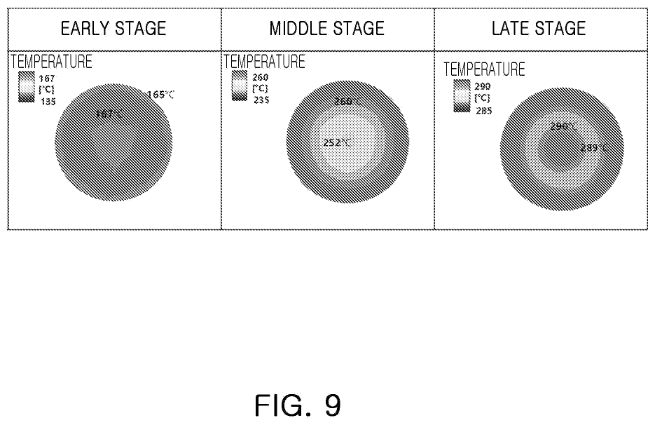

Meanwhile, when the wafer W is heated by the apparatus 100 for heating a wafer as described above, as illustrated in FIG. 9, during the heating process of the wafer W, it can be seen that, a temperature of the central portion of the wafer W at the beginning of the process is approximately 167° C. and a temperature of the edge of the wafer W is approximately 165° C. Thereafter, when heating of the wafer W continues, it can be seen that the temperature of the central portion of the wafer W in the middle of the process is approximately 252° C. and the temperature of the edge of the wafer W is approximately 260° C. In addition, heating of the wafer W continues, and it can be seen that, at the end of the heating process of the wafer W, the temperature of a region having the lowest temperature of the wafer W is approximately 289° C. and the temperature of a region having the highest temperature, that is, the temperature at the central portion and the edge is approximately 290° C. As such, it can be seen that the temperature difference in the entire region of the wafer W is improved to about 1° C. when the wafer W with warpage is heated through the apparatus 100 for heating a wafer according to the example embodiment.

In addition, when the temperature difference in the entire region of the wafer W is improved to about 1° C., a distribution of an ashing rate in an ashing process, which is a post-process, may be reduced by up to 75%.

As described above, by adjusting the heat transfer rate transferred to the wafer W by the stretchable support protrusion 160, the temperature distribution of the wafer W after the wafer heating process may be improved.

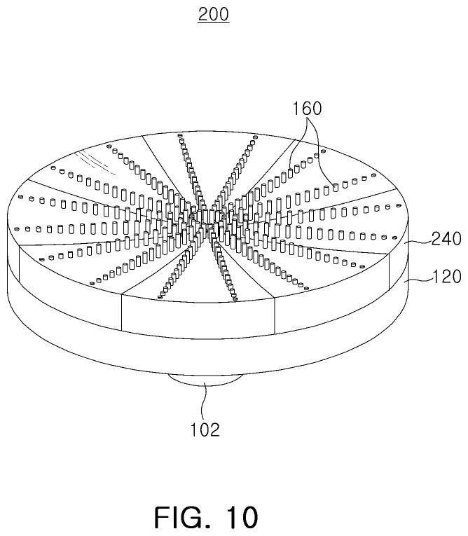

FIG. 10 is a diagram illustrating a heating block of an apparatus for heating a wafer according to an example embodiment.

Referring to FIG. 10, the heating block 240 may be divided into a plurality of blocks, and when installed in the heater 120, the plurality of heating blocks may be assembled to form one heating block 240. However, a division form and division method of the heating block 240 is not limited to the case illustrated in FIG. 10 and the heating block 240 may be divided in various forms and methods.

The apparatus for heating a wafer is capable of reducing a temperature difference of the central portion and the edge of the wafer when heating the wafer with warpage.

While example embodiments have been illustrated and described above, it will be apparent to those skilled in the art that modifications and variations could be made without departing from the scope of the present inventive concept as defined by the appended claims.

What is claimed is:

1. An apparatus for heating a wafer, the apparatus comprising:
a heater;
a heating block on an upper surface of the heater; and
a plurality of support protrusions protruding from an upper surface of the heating block,
wherein the upper surface of the heating block has a curved shape with a concave central portion, and
at least the support protrusion at the central portion of the heating block, among the plurality of support protrusions, is configured to be deformed in response to heating by the heater.

2. The apparatus of claim 1, wherein the support protrusion that is configured to be deformed is deformed when heat or power is supplied thereto.

3. The apparatus of claim 2, wherein the support protrusion that is configured to be deformed comprises a first set of the plurality of support protrusions that are formed of a material stretched or expanded by heat and a second set of the plurality of support protrusions that are formed of a material compressed or contracted by heat.

4. The apparatus of claim 3, wherein the support protrusion that is configured to be deformed is deformed in a vertical length direction.

5. The apparatus of claim 2, wherein the support protrusion that is configured to be deformed is formed of a piezoelectric material or a shape-memory alloy.

6. The apparatus of claim 1, wherein the plurality of support protrusions have a cylindrical shape.

7. The apparatus of claim 1, wherein
a lower end of the support protrusion that is configured to be deformed is received in an insertion recess provided in the heating block, and
deformation of the support protrusion that is configured to be deformed is guided in a vertical length direction by the insertion recess.

8. The apparatus of claim 1, wherein the support protrusion that is configured to be deformed changes in height according to a heating time of the wafer on the plurality of support protrusions.

9. The apparatus of claim 1, wherein upper surfaces of the plurality of support protrusions are coplanar before deformation of the support protrusion that is configured to be deformed.

10. The apparatus of claim 9, wherein before deformation, a difference between a protruding height above the upper surface of the heating block of the support protrusion that is configured to be deformed and a protruding height above the upper surface of the heating block of at least one of the plurality of support protrusions at an outermost edge portion of the heating block is 75 μm to 85 μm.

11. The apparatus of claim 1, wherein
the heating block has a circular shape, and
the plurality of support protrusions are arranged along a line extending radially outwardly from a center of the heating block.

12. The apparatus of claim 1, wherein the heating block is divided into a plurality of portions to be assembled or is integrally formed.

13. The apparatus of claim 1, wherein a material of the support protrusion that is configured to be deformed in the central portion and a material of others of the plurality of support protrusions are different from each other.

14. The apparatus of claim 13, wherein, the others of the plurality of support protrusions excluding the support protrusion that is configured to be deformed are formed of a material including silicon.

15. The apparatus of claim 1, wherein the upper surface of the heating block has a shape corresponding to a shape of the wafer with warpage seated on upper surfaces of the plurality of support protrusions.

16. An apparatus for heating a wafer, the apparatus comprising:
a heater;
a heating block on an upper surface of the heater and having a thickness difference between a central portion and an edge; and
a plurality of support protrusions extending from an upper surface of the heating block, a portion thereof configured to be deformed in response to heat or power supplied thereto.

17. The apparatus of claim 16, wherein, upper surfaces of the plurality of support protrusions, before deformation of the portion of the plurality of support protrusions that are configured to be deformed, are coplanar.

18. The apparatus of claim 17, wherein the portion of the plurality of support protrusions that are configured to be deformed are disposed in a central portion of the heating block.

19. The apparatus of claim 18, wherein the portion of the plurality of support protrusions that are configured to be deformed are formed of a material that is stretched or expanded by heat, and others of the plurality of support protrusions that are configured to be deformed are formed of a material that is compressed or contracted by heat.

20. An apparatus for heating a wafer, the apparatus comprising:
a heater;
a heating block on an upper surface of the heater and having a thickness difference between a central portion and an edge; and
a plurality of support protrusions extending from an upper surface of the heating block, at least some of the plurality of support protrusions configured to be deformed in response to heating by the heater,
wherein the plurality of support protrusions comprise a first support protrusion at the central portion of the heating block that is formed of a material that decreases in height in response to heat, and
wherein the plurality of support protrusions comprise a second support protrusion adjacent the first support protrusion that is formed of a material that increases in height in response to heat.
